(19) United States
(12) Patent Application Publication
(10) Pub. No.: US 2024/0231299 A9
(43) Pub. Date: Jul. 11, 2024

(54) CONTROL CIRCUIT OF HEATING APPARATUS

(71) Applicant: Shenzhen Xinan Textile CO., Ltd, Shenzhen (CN)

(72) Inventor: Jialing XIANG, Shenzhen (CN)

(73) Assignee: Shenzhen Xinan Textile CO., Ltd, Shenzhen (CN)

(21) Appl. No.: 18/078,526

(22) Filed: Dec. 9, 2022

(30) Foreign Application Priority Data
Oct. 25, 2022 (CN) 202222821530.5

(51) Int. Cl. G05B 19/042

(52) U.S. Cl. CPC G05B 19/0425; G01R 27/08

(57) ABSTRACT

The present disclosure relates to a control circuit of a heating apparatus, including a heating control unit, a heating unit, a main control integrated circuit (IC), and a turn-on/off switching unit. The heating control unit is configured to connect or disconnect a path between an external mains supply and the turn-on/off switching unit. The heating unit is connected to the main control IC or the heating control unit via the turn-on/off switching unit. The main control IC is configured to detect an internal resistance of the heating unit, and to control the heating control unit to be turned off when the detected internal resistance exceeds a preset range, thereby improving the safety.

### CROSS-REFERENCE TO RELATED APPLICATIONS

The application claims priority to Chinese patent application No. 202222821530.5, filed on Oct. 25, 2022, the entire contents of which are incorporated herein by reference.

### TECHNICAL FIELD

The present disclosure relates to the technical field of heating apparatuses, in particular to a control circuit of a heating apparatus.

### BACKGROUND

With the rapid development of science and technology, heating apparatuses such as electric blankets, warm clothing, heating waistbands, and physiotherapeutic heaters with warmth preservation or physiotherapy effects are increasingly favored by people.

As contact type electric heaters, especially electric blankets, the safety of heating apparatuses is particularly important. In related technologies, a temperature control unit is usually arranged at a heating wire interface end of a heating apparatus to detect the temperature of the heating wire interface end, which solves the problem of heating wire disconnection caused by local fire at the heating wire interface end and high temperature of an interface.

However, the above solution of arranging the temperature control unit at the heating wire interface end cannot effectively solve the safety problems of sparking caused by damage of the heating apparatus due to itself or external forces and fire due to high temperature, resulting in lower safety.

### SUMMARY

An embodiment of the present disclosure aims to provide a control circuit of a heating apparatus with higher safety.

To solve the above technical problems, an embodiment of the present disclosure provides a control circuit of a heating apparatus, which adopts the following technical solution:

The control circuit of the heating apparatus includes a heating control unit, a heating unit, a main control integrated circuit (IC), and a turn-on/off switching unit, where the heating control unit is arranged between an external mains supply and the turn-on/off switching unit, is connected to the main control IC, and is configured to connect or disconnect a path between the external mains supply and the turn-on/off switching unit; the heating unit is connected to the turn-on/off switching unit and is connected to the main control IC or the heating control unit via the turn-on/off switching unit; and the main control IC is configured to detect an internal resistance of the heating unit, and to control the heating control unit to be turned off when the detected internal resistance exceeds a preset range, so as to cut off the path between the external mains supply and the turn-on/off switching unit.

In preferred solutions of some embodiments, the turn-on/off switching unit includes a first relay, a second relay, and a first drive circuit module; the first relay is connected to a live wire of the external mains supply, a positive connection terminal of the heating unit, and the main control IC, respectively; the second relay is connected to the heating control unit, a negative connection terminal of the heating unit, and the main control IC, respectively; and the first drive circuit module is connected to the main control IC, the first relay, and the second relay, respectively, and is configured to drive opening and closing of the first relay and the second relay.

In preferred solutions of some embodiments, the first drive circuit module includes a first triode, a first current limiting resistor, and a first pull-down resistor; the first triode has a collector connected to the first relay and the second relay, and an emitter connected to the ground; the first current limiting resistor is connected in series between a base of the first triode and the main control IC; and the first pull-down resistor has a terminal connected in parallel to the base of the first triode, and the other terminal connected to the ground.

In preferred solutions of some embodiments, the heating control unit includes a bidirectional silicon controlled rectifier, a silicon controlled rectifier drive integrated circuit (IC), and a second drive circuit module; the bidirectional silicon controlled rectifier is connected to the live wire and a neutral wire of the external mains supply and the silicon controlled rectifier drive IC, respectively; the silicon controlled rectifier drive IC is configured to drive turn-on or turn-off of the bidirectional silicon controlled rectifier; and the second drive circuit module is configured to drive turn-off or turn-on of the silicon controlled rectifier drive IC.

In preferred solutions of some embodiments, the second drive circuit module includes a second triode, a second current limiting resistor, and a second pull-down resistor; the second triode has a collector connected to the silicon controlled rectifier drive IC, and an emitter connected to the ground; the second current limiting resistor is connected in series between a base of the second triode and the main control IC; and the second pull-down resistor has a terminal connected in parallel to the base of the second triode, and the other terminal connected to the ground.

In preferred solutions of some embodiments, the control circuit further includes a rectification unit connected to the external mains supply and the heating control unit, respectively, and configured to rectify an alternating current signal of the external mains supply to be converted into a direct current signal, and to transmit the direct current signal to the heating control unit.

In preferred solutions of some embodiments, the control circuit further includes a voltage reduction unit connected to the rectification unit and the main control IC, respectively, and configured to perform voltage reduction on the direct current signal obtained by conversion via the rectification unit, and to transmit the direct current signal subjected to the voltage reduction to the main control IC.

In preferred solutions of some embodiments, the control circuit further includes a first temperature detection unit connected to the main control IC and configured to detect a temperature of the heating unit and to transmit first temperature data to the main control IC, where the main control IC is configured to control the heating control unit to be turned off when the first temperature data exceeds a preset temperature.

In preferred solutions of some embodiments, the control circuit further includes a circuit board and a second temperature detection unit, where the main control IC, the heating control unit, and the turn-on/off switching unit are all arranged on the circuit board; the second temperature detection unit is configured to detect a temperature of the circuit board and to transmit second temperature data to the main control IC; and the main control IC is configured to control the heating control unit to be turned off when the second temperature data exceeds a preset temperature.

In preferred solutions of some embodiments, the control circuit further includes a voltage detection unit configured to detect a voltage of the input external mains supply and to transmit a detected voltage signal to the main control IC, where the main control IC is configured to control the heating control unit to be turned off when the voltage signal exceeds a preset voltage range.

Compared to the prior art, the control circuit of the heating apparatus provided by the embodiment of the present disclosure has the following beneficial effects:

In the control circuit of the heating apparatus, the turn-on/off switching unit is arranged for switching and connecting the heating unit to the main control IC or the heating control unit; when the heating unit is connected to the heating control unit, the external mains supply provides a working voltage for the heating unit via the heating control unit, and the heating unit generates heat; when the heating unit is connected to the main control IC, the main control IC detects the internal resistance of the heating unit, and controls the heating control unit to be turned off when the detected internal resistance exceeds the preset range, so as to cut off the path between the external mains power and the turn-on/off switching unit, which can achieve the function of stopping heating of the heating unit in a case where the heating unit is damaged and the internal resistance changes; and meanwhile, because the heating unit is switched and connected to the main control IC via the turn-on/off switching unit, it may be ensured that the heating unit is completely disconnected from the external mains supply, thereby improving the safety of the heating apparatus, and enabling a user to use the heating apparatus more safely.

### BRIEF DESCRIPTION OF DRAWINGS

To more clearly illustrate the solution in the present disclosure, the accompanying drawings that need to be used in the description of the embodiment will be briefly introduced below. Apparently, the accompanying drawings in the description below illustrate some embodiments of the present disclosure. Those of ordinary skill in the art may also derive other accompanying drawings from these accompanying drawings without creative efforts. In the accompanying drawings:

FIG. 1 is a structural block diagram of a control circuit of a heating apparatus according to the present disclosure;

FIG. 2 is a circuit diagram of a main control integrated circuit (IC) in the control circuit of the heating apparatus according to the present disclosure;

FIG. 3 is a circuit diagram of a turn-on/off switching unit in the control circuit of the heating apparatus according to the present disclosure;

FIG. 4 is a circuit diagram of a rectification unit, a voltage reduction unit, and a heating control unit in the control circuit of the heating apparatus according to the present disclosure;

FIG. 5 is a circuit diagram of a first temperature detection unit in the control circuit of the heating apparatus according to the present disclosure; and

FIG. 6 is a circuit diagram of a second temperature detection unit in the control circuit of the heating apparatus according to the present disclosure.

Reference numerals in the accompanying drawings are as follows:

10: heating control unit; 11: second drive circuit module; 20: heating unit; 30 (U1): main control IC; 40: turn-on/off switching unit; 41: first drive circuit module; 50: rectification unit; 60: voltage reduction unit; 70: voltage detection unit; 80: first temperature detection unit; 90: display unit; 100: key unit;

J1: first relay; J2: second relay; Q1: first triode; Q2: second triode; R1: first current limiting resistor; R2: first pull-down resistor; R3: second current limiting resistor; R4: second pull-down resistor; D1: freewheeling diode; T1: bidirectional silicon controlled rectifier; U2: silicon controlled rectifier drive integrated circuit (IC); U3: voltage reduction integrated circuit (IC); L1: inductive inductor; NTC1: first temperature sensor; NTC2: second temperature sensor; and NTC3: third temperature sensor.

### DETAILED DESCRIPTION OF THE EMBODIMENTS

All technical and scientific terms used herein have the same meanings as those commonly understood by those skilled in the technical field of the present disclosure, unless otherwise defined. The terms used in the specification are only used for describing specific embodiments, rather than limiting the present disclosure. For example, the orientations or positions indicated by the terms “length”, “width”. “upper”, “lower”, “left”, “right”, “front”, “back”, “vertical”. “horizontal”, “top”. “bottom”, “inside”, “outside”, etc. are orientations or positions shown in the accompanying drawings, which are only convenient for description, and cannot be understood as a limitation to this technical solution.

The terms “include/comprise” and “has/have” and any variations thereof in the specification and claims of the present disclosure and the description of the above accompanying drawings are intended to cover non-exclusive inclusions. The terms “first”, “second”, etc. in the specification and claims of the present disclosure or the above accompanying drawings are used for distinguishing different objects, rather than describing a specific order. “A plurality of” means two or more, unless otherwise expressly and specifically limited.

In the specification and claims of the present disclosure and the description of the above accompanying drawings, when an element is referred to as being “fixed to” or “installed on” or “arranged on” or “connected to” another element, it may be directly or indirectly positioned on another element. For example, when one element is referred to as being “connected to” another element, it may be directly or indirectly connected to another element.

In addition, reference herein to the “embodiments” means that specific features, structures or characteristics described with reference to the embodiments may be included in at least one embodiment of the present disclosure. The appearances of the phrase at various positions in the specification do not necessarily all refer to the same embodiment, and are not independent or alternative embodiments that are mutually exclusive with other embodiments. It is explicitly and implicitly understood by those skilled in the art that the embodiments described herein may be combined with other embodiments.

The heating apparatus is an apparatus capable of generating heat, and provides the beat for people to achieve the warmth preservation or physiotherapy. Specifically, the heating apparatus may be an electronic product such as an electric blanket, warm clothing, a heating waistband, or a physiotherapeutic heater. The present disclosure provides a control circuit of a heating apparatus, which can improve the safety of the heating apparatus.

A preferred embodiment of the control circuit of the heating apparatus according to the present disclosure is described in detail below with reference to the accompanying drawings.

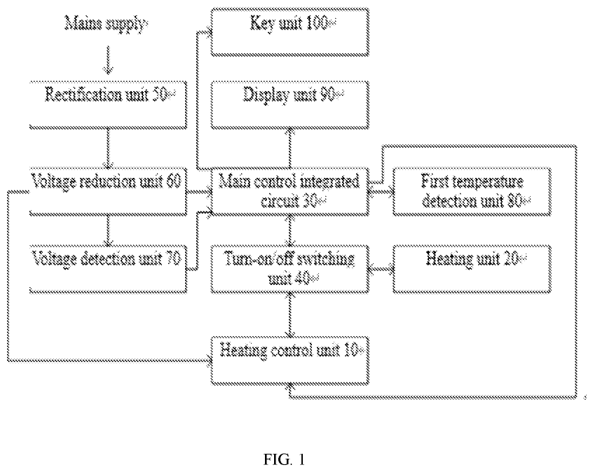

Referring to FIG. 1, the control circuit of the heating apparatus includes a heating control unit 10, a heating unit 20, a main control integrated circuit (IC) 30 (U1), and a turn-on/off switching unit 40.

The heating control unit 10 is arranged between an external mains supply and the turn-on/off switching unit 40, and is connected to the main control IC 30 (U1). The heating control unit 10 is configured to connect or disconnect a path between the external mains supply and the turn-on/off switching unit 40, such that the heating unit 20 can be connected to the external mains supply to obtain a power supply voltage so as to generate heat, or the heating unit 20 is disconnected from the external mains supply to lose the power supply voltage so as to stop heating.

The heating unit 20 is connected to the turn-on/off switching unit 40 and is connected to the main control IC 30 (U1) or the heating control unit 10 via the turn-on/off switching unit 40. In a case where the heating unit 20 is connected to the main control IC 30 (U1), the heating unit 20 is completely disconnected from the heating control unit 10, that is to say, it is completely disconnected from the external mains supply, and the heating unit 20 is not electrified. Herein, the heating unit 20 may be a heating wire, a heating sheet, or other electrically heated part, and a material thereof may be carbon fiber, iron-chromium-aluminum alloy, etc. In this embodiment, the heating unit 20 is preferably the carbon fiber heating wire, with high electro-thermal conversion efficiency, fast, uniform and safe heating, good electrical conductivity, and excellent waterproof and insulation properties.

The main control IC 30 (U1) is configured to detect an internal resistance of the heating unit 20, and to control the heating control unit 10 to be turned off when the detected internal resistance exceeds a preset range, so as to cut off the path between the external mains supply and the turn-on/off switching unit 40. When the internal resistance of the heating unit 20 exceeds the preset range, it indicates that the heating unit 20 is damaged, that is to say, the heating unit 20 is disconnected or partially disconnected, and there will be potential safety hazards in electricity use if it continues to be used.

In the present disclosure, the turn-on/off switching unit 40 is arranged for switching and connecting the heating unit 20 to the main control IC 30 (U1) or the heating control unit 10; when the heating unit 20 is connected to the heating control unit 10, the external mains supply provides a working voltage for the heating unit 20 via the heating control unit 10, and the heating unit 20 generates heat; when the heating unit 20 is connected to the main control IC 30 (U1), the main control IC 30 (U1) detects the internal resistance of the heating unit 20, and controls the heating control unit 10 to be turned off when the detected internal resistance exceeds the preset range, so as to cut off the path between the external mains power and the turn-on/off switching unit 40, which achieves the function of stopping heating of the heating unit 20 in a case where the heating unit 20 is damaged and the internal resistance changes; and meanwhile, because the heating unit 20 is switched and connected to the main control IC 30 (U1) via the turn-on/off switching unit 40, it may be ensured that the heating unit 20 is completely disconnected from the heating control unit 10, that is, the external mains supply, thereby improving the safety of the heating apparatus, and enabling a user to use the heating apparatus more safely.

In specific application, the turn-on/off switching unit 40 may be controlled via the main control IC 30 (U1) every preset time to perform switching to connect the heating unit 20 to the main control IC 30 (U1), and the main control IC 30 (U1) detects the internal resistance of the heating unit 20. When the internal resistance is normal, the turn-on/off switching unit 40 is controlled to perform switching to connect the heating unit 20 to the heating control unit 10, such that the heating unit 20 continues to generate heat.

Herein, the preset time may be a minute. Every minute, the main control IC 30 (U1) will detect the internal resistance of the heating unit 20 and switch back to a heating state of the heating unit 20 after the internal resistance is detected to be normal.

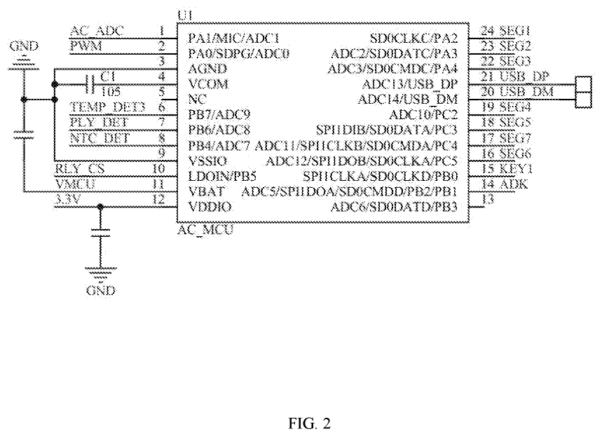

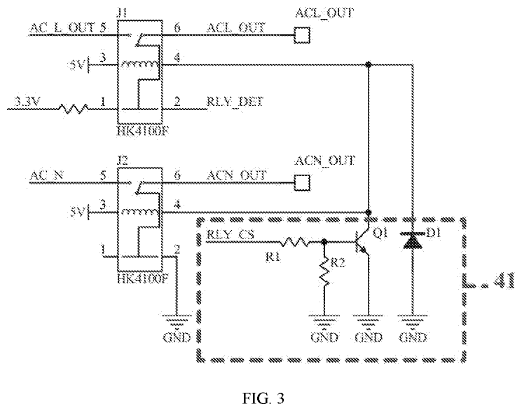

Referring to FIG. 2 to FIG. 4, the turn-on/off switching unit 40 includes a first relay J1, a second relay J2, and a first drive circuit module 41. The first relay J1 is connected to a live wire of the external mains supply, a positive connection terminal of the heating unit 20, and the main control IC 30 (U1), respectively. The second relay J2 is connected to the heating control unit 10, a negative connection terminal of the heating unit 20, and the main control IC 30 (U1), respectively. The first drive circuit module 41 is connected to the main control IC 30 (U1), the first relay J1, and the second relay J2, respectively. The first drive circuit module 41 is configured to drive opening and closing of the first relay J1 and the second relay J2. A circuit diagram of connecting the first relay J1, the second relay J2, and the first drive circuit module 41 to the main control IC 30 (U1) may refer to FIG. 2 and FIG. 3.

When it is needed to detect whether the heating unit 20 is damaged, the main control IC 30 (U1) outputs a signal, the first relay J1 and the second relay J2 are driven via the first drive circuit module 41 to be closed, the positive connection terminal and the negative connection terminal of the heating unit 20 are disconnected from the live wire and a neutral wire of the external mains supply, no power supply voltage is input to the heating unit 20, the heating unit 20 is not electrified, the heating unit 20 is switched and connected to the main control IC 30 (U1), and the main control IC 30 (UL) detects the internal resistance of the heating unit 20. When the detected internal resistance exceeds the preset range, it indicates that the heating unit 20 is damaged and disconnected, the main control IC 30 (U1) controls the heating control unit 10 to be turned off, and the turn-on/off switching unit 40 will not perform switching to connect the heating unit 20 to the external mains supply via the heating control unit 10. When the detected internal resistance is within the preset range, it indicates that the heating unit 20 is normal, the main control IC 30 (U1) outputs a signal, and the first relay J1 and the second relay J2 are driven via the first drive circuit module 41 to be opened, and the heating unit 20 is normally connected to the heating control unit 10 and generates heat normally.

Herein, during the detection of the internal resistance of the heating unit 20 by the main control IC 30 (U1), the internal resistance may be obtained via an existing voltage and current acquisition circuit, and the internal resistance may be compared to a value of the preset range via a comparison logic circuit. A software part does not belong to the improvement of the present disclosure.

In other embodiments, the turn-on/off switching unit 40 may also switch and connect the heating unit 20 to the main control IC 30 (U1) or the external mains supply by using an electronic two-way switch integrated circuit (IC), an integrated switch circuit, etc.

Specifically, referring to FIG. 2 to FIG. 4, the first drive circuit module 41 includes a first triode Q1, a first current limiting resistor R1, and a first pull-down resistor R2. The first triode Q1 has a collector connected to the first relay J1 and the second relay J2, and an emitter connected to the ground. The first current limiting resistor R1 is connected in series between a base of the first triode Q1 and the main control IC 30 (U1), and the first pull-down resistor R2 has a terminal connected in parallel to the base of the first triode Q1, and the other terminal connected to the ground. The first current limiting resistor R1 is configured to limit a current of the base of the first triode Q1, so as to protect the first triode Q1. The first pull-down resistor R2 may prevent misoperation of the main control IC 30 (U1). The main control IC 30 (U1) makes the first triode Q1 on or off by outputting an enable signal, such that the first relay J1 and the second relay J2 are powered on or off to be closed or opened, and then the heating unit 20 is controlled to be switched and connected to the main control IC 30 (U1) or the heating control unit 10.

The first drive circuit module 41 may further include a freewheeling diode D1, and the freewheeling diode D1 has a negative electrode connected to the collector of the first triode Q1, the first relay J1, and the second relay J2, and a positive electrode connected to the ground. The freewheeling diode D1 may smoothen currents released by coils in the first relay 31 and the second relay J2 to protect the first triode Q1.

Of course, in other embodiments, the first drive circuit module 41 may also drive the first relay J1 and the second relay J2 with a drive integrated circuit (IC) dedicated to driving the relays.

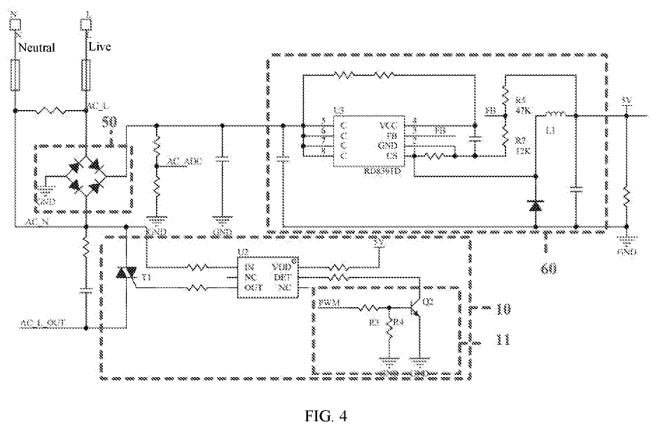

Referring to FIG. 3 and FIG. 4, the heating control unit 10 includes a bidirectional silicon controlled rectifier T1, a silicon controlled rectifier drive IC U2, and a second drive circuit module 11. The bidirectional silicon controlled rectifier T1 is connected to the live wire of the neutral wire of the external mains supply and the silicon controlled rectifier drive IC U2, respectively, and the silicon controlled rectifier drive IC U2 is configured to drive connection or disconnection of the bidirectional silicon controlled rectifier T1. The second drive circuit module 11 is configured to drive turn-off or turn-on of the silicon controlled rectifier drive IC U2. The silicon controlled rectifier drive IC U2 performs high and low voltage isolation to drive the bidirectional silicon controlled rectifier T1 to perform alternating current on-off control on the heating unit 20, so as to achieve heating control on the heating unit 20.

Herein, a model number of the bidirectional silicon controlled rectifier T1 may be BT131-600D, BT134-600E, BT136-600E, BT138-600E, BT139-600E, etc. A model number of the silicon controlled rectifier drive IC U2 may be EL3063.

Specifically, the second drive circuit module 11 includes a second triode Q2, a second current limiting resistor R3, and a second pull-down resistor R4. The second triode Q2 has a collector connected to the silicon controlled rectifier drive IC U2, and an emitter connected to the ground. The second current limiting resistor R3 is connected in series between a base of the second triode Q2 and the main control IC 30 (U1), and the second pull-down resistor R4 has a terminal connected in parallel to the base of the second triode Q2, and the other terminal connected to the ground. The second current limiting resistor R3 is configured to limit a current of the base of the second triode Q2, so as to protect the second triode Q2. The second pull-down resistor R4 may prevent the misoperation of the main control IC 30 (U1). The main control IC 30 (U1) makes the second triode Q2 on or off by outputting an enable signal, such that the silicon controlled rectifier drive IC U2 performs high and low voltage isolation to drive the bidirectional silicon controlled rectifier T1 to perform alternating current on-off control on the heating unit 20, so as to achieve heating control on the heating unit 20.

Referring to FIG. 1 and FIG. 4, the control circuit further includes a rectification unit 50; the rectification unit 50 is connected to the external mains supply and the heating control unit 10, respectively; the rectification unit 50 is configured to rectify an alternating current signal of the external mains supply to be converted into a direct current signal, and to transmit the direct current signal to the heating control unit 10; and power is supplied to the heating unit via the heating control unit 10. The rectified direct current signal may provide a working voltage for the heating unit 20 to achieve heating.

In this embodiment, the control circuit further includes a voltage reduction unit 60; and the voltage reduction unit 60 is connected to the rectification unit 50 and the main control IC 30 (U1), respectively. The voltage reduction unit 60 is configured to perform voltage reduction on the direct current signal obtained by conversion via the rectification unit 50, and to transmit the direct current signal subjected to the voltage reduction to the main control IC 30 (U1). When a voltage signal connected to the mains supply is higher, direct connection to the main control IC 30 (U1) will break down the main control IC 30 (U1). Therefore, the direct current signal obtained by converting the mains supply is subjected to the voltage reduction via the voltage reduction unit 60, and a power supply voltage is provided for the main control IC 30 (U1) after the voltage reduction.

Specifically, referring to FIG. 4, the voltage reduction unit 60 includes a voltage reduction integrated circuit (IC) U3 and an inductive inductor L1. The voltage reduction IC U3 is connected to the rectification unit 50; and the voltage reduction IC U3 outputs a pulse width modulation (PWM) signal to make the inductive inductor L1 generate 5 V induction, which is transmitted to the main control IC 30 (U1) to provide the power supply voltage for the main control IC 30 (U1). A specific circuit diagram of the voltage reduction unit 60 may refer to the figure. Herein, a model number of the voltage reduction IC U3 may be RD8391, etc.

In this embodiment, referring to FIG. 1 and FIG. 4, the control circuit further includes a voltage detection unit 70; the voltage detection unit 70 is configured to detect a voltage of the input external mains supply and to transmit a detected voltage signal to the main control IC 30 (U1); and the main control IC 30 (U1) controls the heating control unit 10 to be turned off when the voltage signal exceeds a preset voltage range.

When the detected voltage signal exceeds the preset voltage range, that is to say, the voltage signal is higher or lower than the preset voltage range, the main control IC 30 (U1) controls the heating control unit 10 to be turned off to cut off the power supply voltage of the heating unit 20, so as to make the heating unit 20 stop heating, which may ensure that the heating apparatus works at a normal voltage, thereby ensuring the safety of electricity use. The preset voltage range may be set according to the power supply safety. For example, when a normal input voltage of the external mains supply is 110 V, the preset voltage range may be set to range from 90 V to 130 V. The detected voltage of below 90 V or above 130 V is considered abnormal.

Specifically, the voltage detection unit 70 may include two sampling resistors connected in series; and the voltage of the input external mains supply may be obtained by acquiring a current of a node for connecting the two sampling resistors in series.

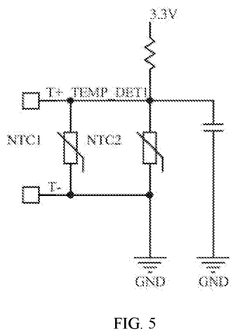

Referring to FIG. 1, FIG. 2, and FIG. 5, the control circuit further includes a first temperature detection unit 80. The first temperature detection unit 80 is connected to the main control IC 30 (U1) and is configured to detect a temperature of the heating unit 20 and to transmit the first temperature data to the main control IC 30 (U1). When the first temperature data exceeds a preset temperature, the main control IC 30 (U1) controls the heating control unit 10 to be turned off.

Herein, when the first temperature data detected by the first temperature detection unit 80 exceeds the preset temperature, it indicates that the heating unit 20 is abnormal in heating, and the main control IC 30 (U1) controls the heating control unit 10 to be turned off. Therefore, the first temperature detection unit 80 may detect abnormal temperature in time to ensure the safety of heating.

A specific circuit of the first temperature detection unit 80 may refer to FIG. 5. The first temperature detection unit 80 includes a first temperature sensor NTC1 and a second temperature sensor NTC2 arranged in parallel; and a node for connecting the first temperature sensor NTC1 to the second temperature sensor NTC2 in parallel is connected to the main control IC 30 (U1), and the other node for parallel connection is connected to the ground. The temperature of the heating unit 20 is detected by using the two temperature sensors, which may improve the accuracy of temperature acquisition.

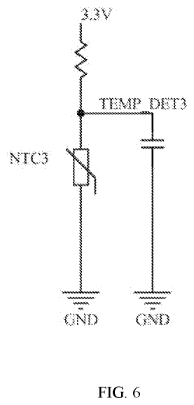

In this embodiment, referring to FIG. 1, FIG. 2, and FIG. 6, the control circuit further includes a circuit board and a second temperature detection unit. The main control IC 30 (U1), the heating control unit 10, and the turn-on/off switching unit 40 are all arranged on the circuit board; and the rectification unit 50 and the voltage reduction unit 60 may also be arranged on the circuit board, the second temperature detection unit is configured to detect a temperature of the circuit board and to transmit second temperature data to the main control IC 30 (U1); and the main control IC 30 (U1) is configured to control the heating control unit 10 to be turned off when the second temperature data exceeds a preset temperature. When the components on the circuit board work abnormally to generate heat to cause the temperature of the circuit board to be abnormal, the second temperature detection unit will detect the abnormality, and the main control IC 30 (U1) timely turns off the heating control unit 10 to turn off the heating unit 20, thereby further ensuring normal operation of the heating apparatus.

Specifically, the second temperature detection unit may be a third temperature sensor NTC3. The third temperature sensor NTC3 has a terminal connected to the main control IC 30 (U1) and the other terminal connected to the ground. The main control IC 30 (U1) may obtain the second temperature data of the third temperature sensor NTC3, and then compare it with the preset temperature to determine whether the temperature of the circuit board is abnormal.

In this embodiment, the control circuit further includes a display unit 90 connected to the main control IC 30 (U1). The display unit 90 may be configured to display an error code when the temperature of the heating unit 20 or the circuit board is abnormal, or the input of the external mains supply is abnormal.

The control circuit further includes a key unit 100 connected to the main control IC 30 (UL). The key unit 100 may be configured to set the increase and decrease of the heating temperature and heating time which may also be displayed on the display unit 90.

The above descriptions are merely the preferred embodiments of the present disclosure, and are not used for limiting the present disclosure. For those skilled in the art, various modifications and variations of the present disclosure are possible. Any modifications, equivalent substitutions, improvements, etc. made within the spirit and principle of the present disclosure should be included in the scope of the claims of the present disclosure.

What is claimed is:

1. A control circuit of a heating apparatus, comprising a heating control unit, a heating unit, a main control integrated circuit (IC), and a turn-on/off switching unit, wherein
the heating control unit is arranged between an external mains supply and the turn-on/off switching unit, is connected to the main control IC, and is configured to connect or disconnect a path between the external mains supply and the turn-on/off switching unit;
the heating unit is connected to the turn-on/off switching unit and is connected to the main control IC or the heating control unit via the turn-on/off switching unit; and
the main control IC is configured to detect an internal resistance of the heating unit, and to control the heating control unit to be turned off when the detected internal resistance exceeds a preset range, so as to cut off the path between the external mains supply and the turn-on/off switching unit.

2. The control circuit according to claim 1, wherein the turn-on/off switching unit comprises a first relay, a second relay, and a first drive circuit module; the first relay is connected to a live wire of the external mains supply, a positive connection terminal of the heating unit, and the main control IC, respectively; the second relay is connected to the heating control unit, a negative connection terminal of the heating unit, and the main control IC, respectively; and the first drive circuit module is connected to the main control IC, the first relay, and the second relay, respectively, and is configured to drive opening and closing of the first relay and the second relay.

3. The control circuit according to claim 2, wherein the first drive circuit module comprises a first triode, a first current limiting resistor, and a first pull-down resistor; the first triode has a collector connected to the first relay and the second relay, and an emitter connected to the ground; the first current limiting resistor is connected in series between a base of the first triode and the main control IC; and the first pull-down resistor has a terminal connected in parallel to the base of the first triode, and the other terminal connected to the ground.

4. The control circuit according to claim 1, wherein the heating control unit comprises a bidirectional silicon controlled rectifier, a silicon controlled rectifier drive integrated circuit (IC), and a second drive circuit module; the bidirectional silicon controlled rectifier is connected to a live wire and a neutral wire of the external mains supply and the silicon controlled rectifier drive IC, respectively; the silicon controlled rectifier drive IC is configured to drive turn-on or turn-off of the bidirectional silicon controlled rectifier; and the second drive circuit module is configured to drive turn-off or turn-on of the silicon controlled rectifier drive IC.

5. The control circuit according to claim 4, wherein the second drive circuit module comprises a second triode, a second current limiting resistor, and a second pull-down resistor; the second triode has a collector connected to the silicon controlled rectifier drive IC, and an emitter connected to the ground; the second current limiting resistor is connected in series between a base of the second triode and the main control IC; and the second pull-down resistor has a terminal connected in parallel to the base of the second triode, and the other terminal connected to the ground.

6. The control circuit according to claim 1, further comprising a rectification unit connected to the external mains supply and the heating control unit, respectively, and configured to rectify an alternating current signal of the external mains supply to be converted into a direct current signal, and to transmit the direct current signal to the heating control unit.

7. The control circuit according to claim 6, further comprising a voltage reduction unit connected to the rectification unit and the main control IC, respectively, and configured to perform voltage reduction on the direct current signal obtained by conversion via the rectification unit, and to transmit the direct current signal subjected to the voltage reduction to the main control IC.

8. The control circuit according to claim 1, further comprising a first temperature detection unit connected to the main control IC and configured to detect a temperature of the heating unit and to transmit first temperature data to the main control IC, wherein the main control IC is configured to control the heating control unit to be turned off when the first temperature data exceeds a preset temperature.

9. The control circuit according to claim 1, further comprising a circuit board and a second temperature detection unit, wherein the main control IC, the heating control unit, and the turn-on/off switching unit are all arranged on the circuit board; the second temperature detection unit is configured to detect a temperature of the circuit board and to transmit second temperature data to the main control IC; and the main control IC is configured to control the heating control unit to be turned off when the second temperature data exceeds a preset temperature.

10. The control circuit according to claim 1, further comprising a voltage detection unit configured to detect a voltage of the input external mains supply and to transmit a detected voltage signal to the main control IC, wherein the main control IC is configured to control the beating control unit to be turned off when the voltage signal exceeds a preset voltage range.
